(19) United States
(12) Patent Application Publication
(10) Pub. No.: US 2004/0185586 A1
(43) Pub. Date: Sep. 23, 2004

(54) Preparation of sample chip, method of observing wall surface thereof and system therefor

(76) Inventors: Masatoshi Yasutake, Chiba-shi (JP); Yoshimi Kanno, Miyagi (JP); Tsugio Sakai, Miyagi (JP)

Correspondence Address: ADAMS & WILKS, 31st Floor, 50 Broadway, New York, NY, 10004, US

(21) Appl. No.: 10/775,724

(22) Filed: Feb. 10, 2004

(30) Foreign Application Priority Data
Feb. 13, 2003 (JP) 2003-034599

(51) Int. Cl. H01L 21/66; G01R 31/26

(52) U.S. Cl. 438/14

(57) ABSTRACT

When trying to check the lamination structure of devices advanced in scaling and integration, SEM observation is insufficient in resolution. TEM observation presents a problem such that high throughputs cannot be achieved because it is required to prepare a sample for TEM observation. To include: a focused ion beam apparatus for processing a sample surface and preparing a sample chip; a pick-up apparatus for picking up the sample chip; a sample chip holder for securing the sample chip picked up; an argon ion beam irradiating apparatus for etching a surface of the sample chip secured to the sample chip holder with an argon ion beam; and a SPM for observing the surface of the sample chip secured to the sample chip holder.

### BACKGROUND OF THE INVENTION

1. Field of the Invention

The present invention relates to the preparation of a sample chip and a method of observing its wall surface and a system therefor.

In recent years, various types of devices including semiconductor devices and display devices have been becoming finer and more complicated in structure owing to the increase of capabilities. In particular, the elements and interconnections, which make up the devices, are of lamination structures resulting from stacking thin films of a level of a few atomic layers and as such, the needs for observation of the structures thereof have been high.

The invention allows a desired area in a sample, such as a wafer, to be cut off as a sample chip and a side wall or bottom face of the sample chip to be observed through a scanning probe microscope (SPM). The invention was made for the purpose of contributing to the evolution of devices in research and development, production process management, failure analysis, etc.

2. Description of the Related Art

As a first technique, there is known a method of forming a cross-sectional structure exposed portion in a desired area in a sample surface with a focused ion beam to observe the exposed cross section through a scanning ion microscope image by a focused ion beam or a scanning electron microscope (SEM) image by electron beam scanning (see Kaito et al. “Focused Ion Beam System for IC Development and Its Applications,” 1st Micro Process Conference, 1988, for example).

As a second technique, there is known a method of etching a desired area in a sample surface with a focused ion beam to take out a sample chip and observing the sample chip with a transmission electron microscope (TEM) (see JP-A-05-52721, p.4-5, FIG. 1, for example).

The first conventional technique has presented a problem of an insufficient resolution for observation in observing a cross-sectional structure of a sample using a scanning ion beam microscope image or SEM image. Also, SEM images have presented a problem of insufficient resolution for management of film thicknesses. The reason for this is that in regard to the SEM image spatial resolution a spacial resolution of about one (1) nanometer is known to be the best performance that can be achieved by SEMs, while a thickness of the thinnest one of film structures forming a sample is of the order of one (1) nanometer.

According to the second conventional technique, TEM images are used for cross-sectional structure observation of samples. TEMs have sufficient spatial resolutions because they enable observation of fundamental particles forming a film structure. However, there has been a problem such that TEMs are very expensive.

Also, TEMs have presented a problem such that they can provide only averaged or integrated information for the geometry developed by many atomic layers because TEMs form an observation image based on the information attained by causing electrons to pass through a sample. In addition, TEMs can provide neither information on electrical properties of a sample, such as sample's electrical conductivities, dopant concentrations, dielectric constants, electric potentials, leaking magnetic fields and spin interactions, nor information on mechanical properties including a sample hardness, frictions and elasticoviscosities, other than the geometry of a sample cross section. Therefore, comprehensive analyses of a sample chip cannot be performed with TEMs.

### SUMMARY OF THE INVENTION

The invention was made in order to solve the above problems.

A sample chip is cut off from a sample by scanning and irradiating a desired area in a sample surface with a focused energy beam thereby to carry out an etching process. The sample chip cut off is taken up with a pick-up apparatus. The surface, side wall, or bottom face of the taken sample chip are observed with a multi-function SPM.

### BRIEF DESCRIPTION OF THE DRAWINGS

FIGS. 1A-1H are illustrations of assistance in explaining a method according to the invention;

FIG. 2 is a view showing an example of sample chip holders

FIG. 3 is a flowchart for the method according to the invention;

FIGS. 4A-4E are conceptual illustrations for an apparatus constituting a system according to the invention; and

FIGS. 5A and 5B are conceptual illustrations of an SPM according to the invention.

### EMBODIMENTS

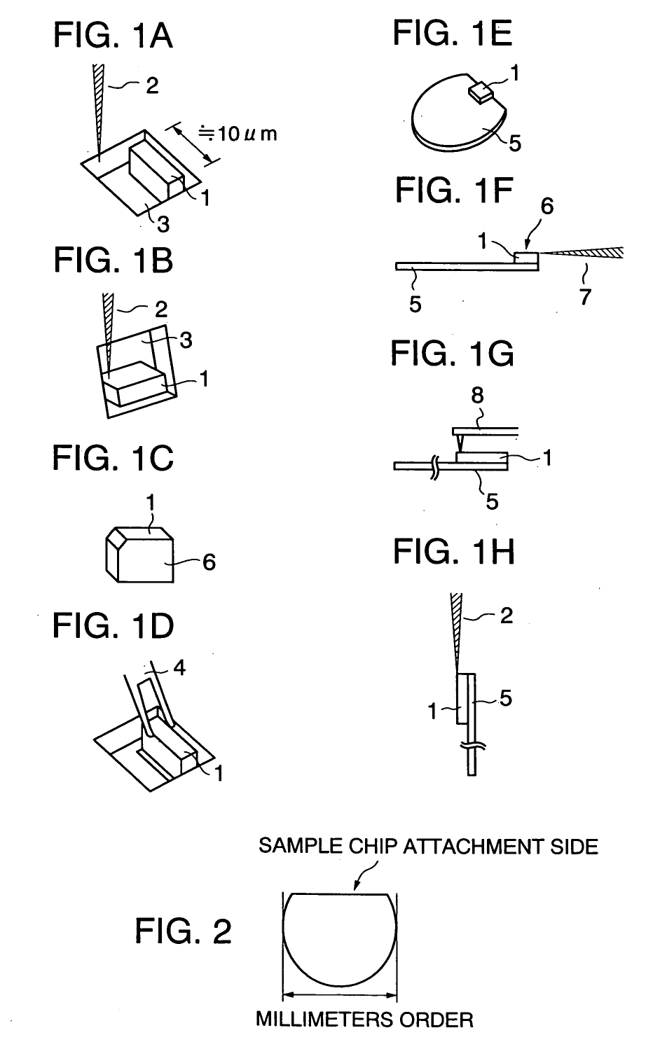

Referring to FIGS. 1A-1H, the method of the invention will be described.

As shown in FIG. 1A, a focused ion beam (FIB) 2 is applied to a surrounding area around a predetermined area of a sample, where a sample chip 1 is to be formed, whereby an etching process is carried out to produce a hole 3. In regard to the size of the sample chip 1, the preparation time of the sample chip is elongated if the size is larger, and it becomes difficult to pick up the sample chip if its size is smaller. When a step for picking up the sample chip with a pick-up apparatus, which is to be described later, is carried out under an optical microscope, the proper sample chip size is considered to be about 10 μm in width. In the case where the surface to be observed with the SPM is a side wall, a damaged layer formed by focused ion beam processing can be removed by blowing an etching gas against the side wall, i.e. observed surface. In this step, the side wall may be irradiated with an electron beam or a laser beam simultaneously. In addition, a stepped portion according to the difference among materials making up the observed surface may be formed based on the difference utilizing the fact an etching rate depends on the material.

As shown in FIG. 1B, a focused ion beam 2 is applied at an incident angle different from that in performing the process shown in FIG. 1A in order to cut off a predetermined area of the sample as a sample chip, whereby an etching process is carried out to separate the sample chip 1 from the sample.

In this step, it is also useful to process the sample chip 1 into an asymmetric form on the right and left of the observed surface 6 as you face it as shown in FIG. 1C, thereby to clearly indicate an observed surface for the SPM.

The sample chip 1 cut away is picked up with micro tweezers 4 as shown in FIG. 1D.

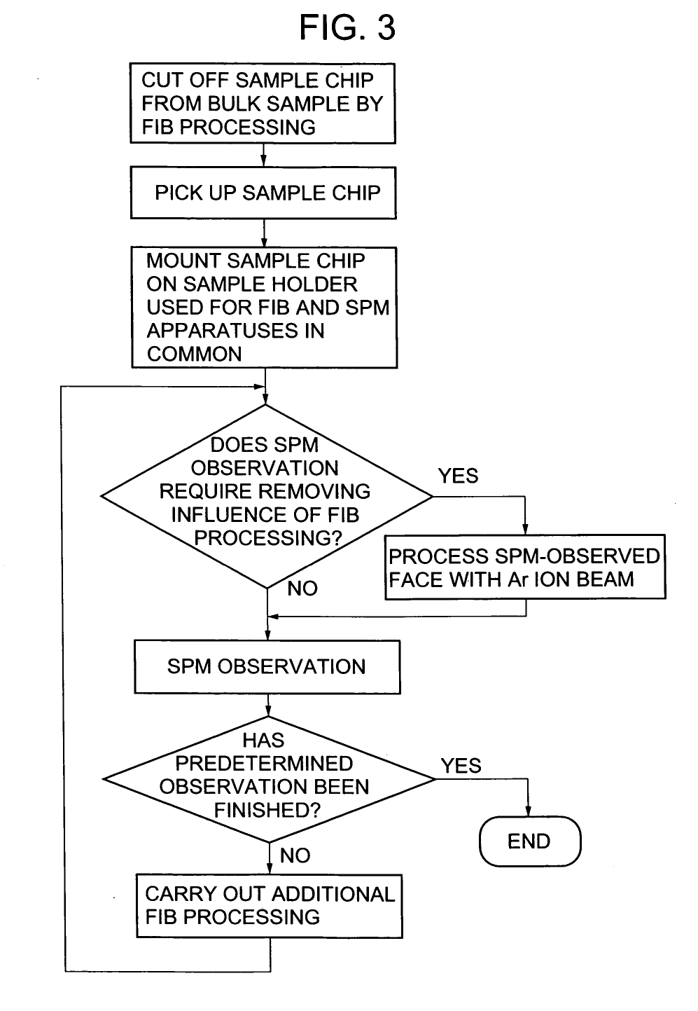

Then, the picked sample chip 1 is secured to a sample chip holder 5 with an SPM-observed surface upward as shown in FIG. 1E. The observed surface is checked on the asymmetric sample chip form shown in FIG. 1C. In this case, the sample chip holder 5 is of a size such that an operator can check with the naked eye the side which the sample chip is attached on for example as shown in FIG. 2. The sample chip 1 can be secured to the sample chip holder 5 using an adhesive.

Subsequently, as shown in FIG. 1F, the sample chip holder 5 with the sample chip 1 secured thereto is loaded into an argon (Ar) ion beam irradiating apparatus, and then the observed surface 6 of the sample chip 1 is irradiated with an Ar ion beam 7 from the tangent direction of the observed surface 6. A damaged layer resulting from the focused ion beam processing is removed in the observed surface 6 for an SPM by applying an Ar ion beam, provided that it is not necessary to do this in the case where such damaged layer doesn't affect the observation by an SPM. However, it is not allowed to ignore the affect of the damaged layer, for example, in the case of observing with a scanning capacitance microscope. Accordingly, this step can not be eliminated.

Then, as shown in FIG. 1G, the sample chip holder 5 with the sample chip 1 secured thereto is set on a sample table of the SPM 8 to perform the microscopic observation of the observed surface. If this observation provides a predetermined microscope image, the operation is completed.

In the case where desired microscope image could not be obtained or the case where a portion below the observed surface 6 is to be observed, the sample chip holder 5 with the sample chip 1 secured thereto is loaded into a focused ion beam irradiating apparatus, as shown in FIG. 1H, to apply a focused ion beam 2 to the sample chip 1 from the tangent direction of the observed surface of the sample chip, thereby additionally etching the surface of the observed surface. In this step, as shown in FIG. 1H, the sample chip holder 5 is so arranged that the side where the sample chip 1 is secured is to undergo the irradiation of a focused ion beam 2. This allows a processed region to be placed at a position where the focused ion beam is focused.

After that, the step shown in FIG. 1F and the subsequent steps thereafter are repeated only a required number of times.

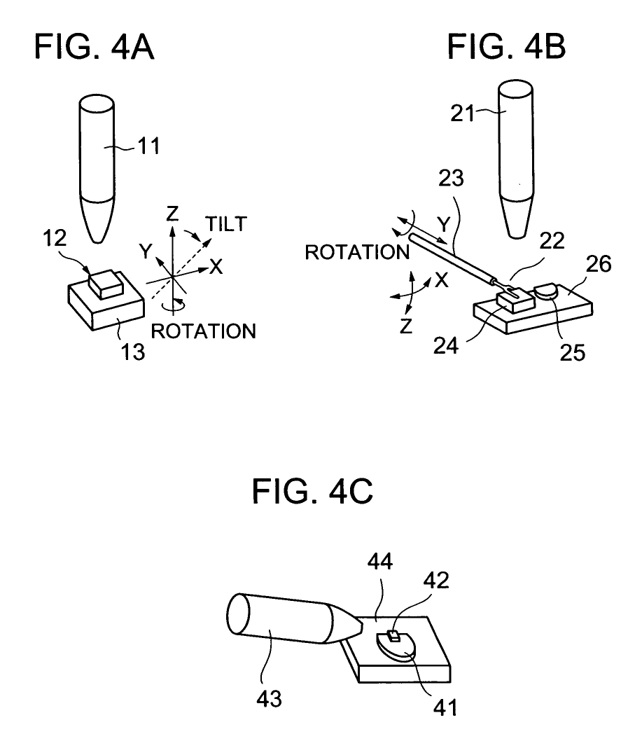

Series of the above steps are shown in the flowchart of FIG. 3.

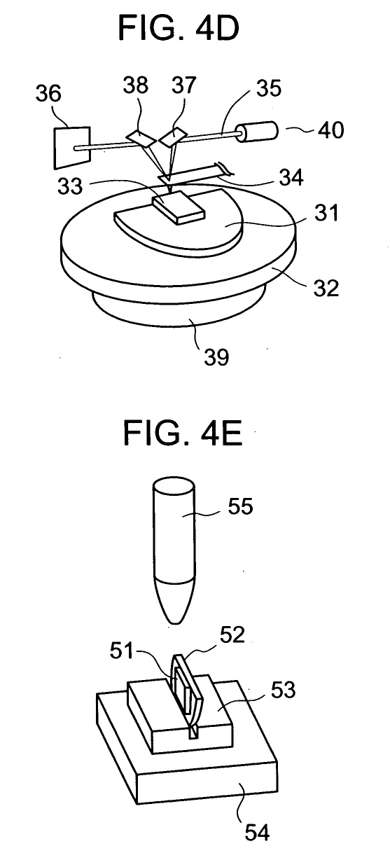

In addition, the conceptual illustrations of the apparatuses constituting the system for conducting these steps are presented by FIGS. 4A-4E.

The conceptual illustration of a focused ion beam apparatus is presented by FIG. 4A. The focused ion beam apparatus includes at least a focused ion beam irradiating system 11, a sample stage 13 capable of securing a sample 12, moving the sample in X, Y and Z directions, rotating its X-Y plane about the Z-axis and tilting the X-Y plane, and a vacuum chamber (not shown) which is mounted with the irradiating system and sample stage and the inside of which can be maintained under vacuum. The surface of the sample 12 put on the sample stage 13 is irradiated with a focused ion beam. As a result, a sample chip is prepared by sputter-etching.

The conceptual illustration of the pick-up apparatus is presented by FIG. 4B. The pick-up apparatus includes at least a microscope 21 capable of observing a sample chip, tweezers 22 for picking up the sample chip, a manipulator 23 capable of shifting the position of the tweezers in the three-dimensional space and rotating the tweezers about Y-axis, and a sample table 26 which a sample 24 machined by the focused ion beam apparatus and the sample chip holder 25 for securing the sample chip picked up are put on. The sample table 26 is capable of moving the sample chip and the sample chip holder 25 to a position where they can be observed through the microscope 21. The microscope 21 may be an optical microscope when the sample chip is of a size of about 10 μm. However, in the case of handling a sample smaller than 10 μm, it is required to use a microscope with a higher resolution, e.g. a SEM and a scanning ion microscope. In this case, the manipulator and the sample table are arranged so as to be maintained under vacuum. The sample chip, which has been cut away from the sample, is picked up with the tweezers while observing it with the microscope and then moved onto the sample chip holder 25. In this step, when a plurality of sample chips are formed with the sample 24, on the sample table 26 are put only as many sample chip holders 25 as there are the sample chips.

The conceptual illustration of an SPM using an optical lever technique is presented by FIG. 4D. In the SPM, a sample surface is microscopically observed by making a probe having a sharp tip scan the observed surface of the sample chip 33 on the sample chip holder 31 put on the sample table 32 lying over the piezo-scanner 39. By making the probe mounted on the tip of the cantilever 34 scan the observed surface of the sample, variations in height following the stepped portions in the top face of the observed surface are determined based on the displacement of the light entering the optical sensor 36 through the mirror 38, which is produced by a laser beam 35 launched from the laser source 40 through the mirror 37 and reflected from the rear of the cantilever. Although an example of optical lever techniques is presented here, generally-known, other optical lever techniques, a self-detection technique using a cantilever mounted with a strain sensor, or the like may be adopted. In regard to the SPM, there are known various types of SPMs including a contact type atomic force microscope (AFM) described in detail in U.S. Pat. No. 4,935,634, and a non-contact type AFM reported by Martin, et al. in J. Applied Physics, 61(10), 15 May 1987. However, the SPM here is not limited to any type of SPM. It is essential only that the SPM be of any type which enables two-dimensional microscopic observation of various kinds of information on an extremely fine region including the geometry of a sample surface.

In this connection, it is possible to select a microscope of an optimal measurement mode according to the information desired to derive from the sample chip, in other words, so as to meet the purpose of the observation, etc. The electromagnetic measurements, mechanical measurements and geometrical measurements with high resolution will be described below.

First, examples of electromagnetic measurement with respect to a sample chip will be described. In the case of measuring dopant concentrations or dielectric constants, the steps below are followed: to dispose a highly sensitive capacitance detector in proximity to a probe; to apply an alternating voltage (AC voltage) from the bias voltage source to the sample; to detect a change in capacitance just under the probe synchronously; and to calculate the dopant concentration or dielectric constant of the sample based on the detected change of the capacitance. Further, in the case of measuring a current flowing through a sample chip, the steps below are followed: to place a conducting probe in contact with a portion to be measured; to scan a voltage according to a bias voltage source; to detect a current flowing at that time with the micro-ampere meter described above; and to determine an I/V curve at the contact point. Alternatively, the probe may be made to scan the portion to be measured with the bias voltage kept constant, thereby to carry out current image mapping. In the case of measuring a sample chip in potential, the steps below are followed: to apply an AC voltage to the sample plane; to control the voltage of the bias voltage source so that the amplitude of the cantilever oscillating according to the frequency of the AC electric field reaches zero; and to determine a surface potential of the sample based on the control voltage. Finally, in the case of using a magnetic-force microscope, a magnetic probe is used to determine a magnetic domain where the magnetic leakage appears within the surface of the sample chip.

Second, examples of measurement of mechanical properties with respect to a sample chip will be described. The information on friction in a sample plane is measured by a friction force microscope. The difference in friction force provides contrast for the substances of stacked layers, and as such, the film thicknesses of the stacked layers can be measured. Also, the difference in friction force arising in the sample chip surface enables the detection of contaminations, etc. in stacked materials. Now, in regard to the information on the hardness of a sample chip plane, the probe is brought into contact with the sample plane to provide it with infinitesimal vibrations. The difference in vibrational phase between the power supply that provides the infinitesimal vibrations and the probe provides the hardness information of the sample plane.

Various sample chip holders are needed in order to secure the above-mentioned sample chips and perform SPM measurements easily. These sample chip holders includes: a sample chip holder with its surface coated with a conducting metal and with the capabilities of flowing a current through a sample chip, as described above, and grounding the sample chip; a sample chip holder with a low-melting-point metal, e.g. indium (In), on the surface thereof, having a mechanism such that the sample chip holder and the sample chip are heated to melt the low-melting-point metal prior to measurements, thereby to secure the sample chip to the holder and establish good conductivity between the sample chip and the sample chip holder; a sample chip holder with a low-melting-point polymer on the surface thereof, in which the sample chip holder and the sample chip are heated to melt the low-melting-point polymer thereby to secure the sample chip to the holder and isolate the sample chip from the sample chip holder; and a sample chip holder having a flat insulator substrate such as Macor(R), to which the sample chip is secured, and a plurality of electrodes disposed so as to surround the sample chip, wherein these electrodes can be wired to the sample chip electrodes by wire bonding, etc.

The conceptual illustration of the Ar ion beam irradiating apparatus is presented by FIG. 4C. The Ar ion beam irradiating apparatus includes a sample table 44 with the sample chip holder 41 put thereon, an Ar ion beam irradiating system 43, and a vacuum chamber (not shown) for maintaining the sample table and Ar ion beam irradiating system under vacuum. An Ar ion beam is applied to of an observed surface the sample chip 42 from a tangent direction of the observed surface to thinly etch a top face of the observed surface. Applying an Ar ion beam from the tangent direction of the observed surface can minimize the damage in the observed surface resulting from Ar ion beam irradiation and avoid leaving the things produced by the processing on the observed surface.

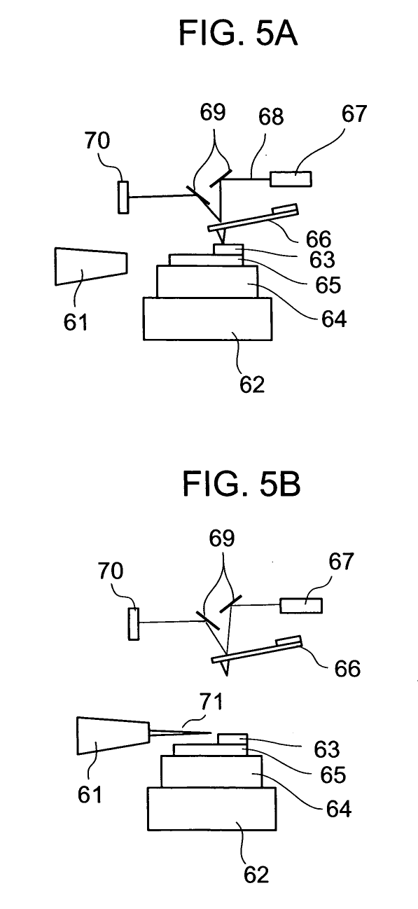

Also, the Ar ion beam irradiating apparatus may be integrated into an SPM as shown in FIGS. 5A-5B. The SPM includes the above-described arrangement and the Ar ion beam irradiating system 61 as well as a vacuum chamber (not shown) for maintaining them under vacuum. FIG. 5A shows that the sample stage 62 is in a position which permits the observation of the observed surface of the sample chip 63 through the SPM. FIG. 5B shows that the sample stage 62 has been shifted downward to retreat the sample chip 63 from the position which permits the observation with the SPM and been in a position such that an Ar ion beam 71 can be applied to the sample chip. This can prevent the Ar ion beam irradiation from causing damage to the probe of the SPM. In this case, a new observed surface exposed by the Ar ion beam irradiation can be observed through the SPM without exposing the new surface to the atmosphere.

In the case of microscopically observing an observed surface of the sample chip with the SPM and further observing a region underlying the observed surface, the observed surface is etched with the focused ion beam apparatus or Ar ion beam irradiating apparatus to expose a new observed surface.

In the case of using the focused ion beam apparatus, the focused ion beam apparatus is so arranged that the sample chip holder 52 can be mounted on the sample stage 54 through the sample chip holder supporting member 53 in a position such that a focused ion beam is applied from a tangent direction of the observed surface of the sample chip 51, as shown in FIG. 4E. The reference numeral 55 here indicates a focused ion beam irradiating system for launching a focused ion beam. In this step, when the focused ion beam apparatus used for preparation of the sample chip is, for example, a wafer-specific machine, another focused ion beam apparatus adapted for this work may be used.

The invention brings the following advantages.

1. A sample is irradiated with a focused energy beam to prepare a sample chip, followed by observing a side wall of the sample chip with an SPM. This makes it possible to observe the geometry of a sample surface or sample inside in a predetermined area of the sample with an atomic level resolution.

2. A sample is irradiated with a focused energy beam to prepare a sample chip, followed by: observing a side wall of the sample chip with an SPM; irradiating an observed surface with a focused energy beam from a tangent direction thereof to etch the surface and expose a new observed surface; and observing the new surface with the SPM again. By repeating the above steps, it becomes possible to observe the geometry of a sample surface or sample inside in a predetermined area of the sample and the three-dimensional distribution thereof with an atomic level resolution.

3. A sample is irradiated with a first focused energy beam to prepare a sample chip, followed by irradiating an observed surface with a second focused energy beam from a tangent direction of the observed surface to remove a damaged layer in the surface in a side wall of the sample chip, which results from the focused energy beam irradiation processing, and then observing the observed surface in the side wall of the sample chip with an SPM. This makes it possible to observe the geometry of the sample surface or sample inside in a predetermined area of the sample and the distributions of various characteristics (resistance, capacitance, magnetism, etc.) with a high resolution.

4. A sample is irradiated with a first focused energy beam to prepare a sample chip, followed by: irradiating an observed surface with a second focused energy beam from a tangent direction of the surface to remove a damaged layer in the observed surface in a side wall of the sample chip, which results from the focused energy beam irradiation processing; observing the resultant observed surface in the side wall of the sample chip with the SPM; irradiating the observed surface with a second focused energy beam from a tangent direction of the surface to etch the surface and expose a new observed surface; and observing the new surface with the SPM again. By repeating the above steps, it becomes possible to observe the geometry of a sample surface or sample inside in a predetermined area of the sample, the distributions of various characteristics (resistance, capacitance, magnetism, etc.), and the three-dimensional distributions thereof with a high resolution.

5. A sample is irradiated with a first focused energy beam to prepare a sample chip, followed by: irradiating an observed surface with a second focused energy beam from a tangent direction of the surface to remove a damaged layer in the observed surface in a side wall of the sample chip, which results from the focused energy beam irradiation processing; observing the resultant observed surface in the side wall of the sample chip with an SPM; irradiating the observed surface with the first focused energy beam from a tangent direction of the surface to etch the surface and expose a new observed surface; removing a damaged layer with the second focused energy beam again; and then observing the new surface with the SPM. By repeating the above steps, it becomes possible to observe the geometry of a sample surface or sample inside in a predetermined area of the sample, the distributions of various characteristics (resistance, capacitance, magnetism, etc.), and the three-dimensional distributions thereof with a high resolution.

6. A system is constructed, which includes a focused ion beam apparatus for preparing a sample chip, a pick-up apparatus for picking up the sample chip, an Ar ion beam irradiating apparatus for removing a damaged layer formed in an observed surface of the sample chip, an SPM for observing a side wall of the sample chip, and a sample chip holder capable of being used in common in these apparatuses. This makes it possible to observe the geometry of a sample surface or sample inside in a predetermined area of the sample, the distributions of various characteristics (resistance, capacitance, magnetism, etc.), and the three-dimensional distributions thereof with a high resolution.

What is claimed is:

1. A method of preparing a sample chip and observing its wall surface, comprising:
a first step including irradiating a sample with a focused energy beam, etching a surrounding area and a bottom portion of a predetermined area, and making the sample chip;
a second step of taking out the sample chip from the sample; and
a third step of observing a wall surface of the taken sample chip with a scanning probe microscope (SPM).

2. The method of preparing a sample chip and observing its wall surface of claim 1, wherein said focused energy beam is a focused ion beam.

3. The method of preparing a sample chip and observing its wall surface of claim 2, wherein said first step includes processing the sample chip so that a stepped portion according to difference in material is formed in a surface to be observed with the scanning probe microscope.

4. A method of preparing a sample chip and observing its wall surface, comprising:
a first step including irradiating a sample with a focused energy beam, etching a surrounding area and a bottom portion of a predetermined area, and making the sample chip;
a second step of taking out the sample chip from the sample;
a third step of observing a wall surface of the taken sample chip with a scanning probe microscope;
a fourth step of irradiating the SPM-observed surface of the taken sample chip with the focused energy beam thereby to etch the SPM-observed surface; and
a step of repeating said third and fourth steps only a required number of times again.

5. The method of preparing a sample chip and observing its wall surface of claim 4, wherein said focused energy beam is a focused ion beam.

6. The method of preparing a sample chip and observing its wall surface of claim 5, wherein said first step includes processing the sample chip so that a stepped portion according to difference in material is formed in a face to be observed with the scanning probe microscope.

7. A method of preparing a sample chip and observing its wall surface, comprising:
a first step including irradiating a sample with a first focused energy beam, etching a surrounding area and a bottom portion of a predetermined area, and making the sample chip;
a second step of taking out the sample chip from the sample;
a third step of irradiating a specified wall surface, which the SPM-observed surface of the taken sample chip makes, with a second focused energy beam thereby to etch the wall surface; and
a fourth step of observing the wall surface of the sample chip, which has undergone the etching by the second focused energy beam in said third step.

8. The method of preparing a sample chip and observing its wall surface of claim 7, wherein said first focused energy beam is a focused ion beam, and
said second focused energy beam is an argon ion beam.

9. The method of preparing a sample chip and observing its wall surface of claim 8, wherein said first step includes processing the sample chip so that a stepped portion according to difference in material is formed in a face to be observed with the scanning probe microscope.

10. A method of preparing a sample chip and observing its wall surface, comprising:
a first step including irradiating a sample with a first focused energy beam, etching a surrounding area and a bottom portion of a predetermined area, and making the sample chip;
a second step of taking out the sample chip from the sample;
a third step of irradiating a specified wall surface, which the SPM-observed surface of the taken sample chip makes, with a second focused energy beam thereby to etch the wall surface;
a fourth step of observing the wall surface of the sample chip, which has undergone the etching by the second focused energy beam in said third step;
a fifth step of irradiating the SPM-observed surface of the taken sample chip with the first focused energy beam thereby to etch the SPM-observed surface; and
a step of repeating said third to fifth steps only a required number of times again.

11. The method of preparing a sample chip and observing its wall surface of claim 10, wherein said first focused energy beam is a focused ion beam, and
said second focused energy beam is an argon ion beam.

12. The method of preparing a sample chip and observing its wall surface of claim 11, wherein said first step and/or fifth step include processing the sample chip so that a stepped portion according to difference in material is formed in a face to be observed with the scanning probe microscope.

13. A method of preparing a sample chip and observing its wall surface, comprising:
a first step including irradiating a sample with a first focused energy beam, etching a surrounding area and a bottom portion of a predetermined area, and making the sample chip;
a second step of taking out the sample chip from the sample;
a third step of irradiating a specified wall surface, which the SPM-observed surface of the taken sample chip makes, with a second focused energy beam thereby to etch the wall surface;
a fourth step of observing the wall surface of the sample chip, which has undergone the etching by the second focused energy beam in said third step;
a fifth step of irradiating the SPM-observed surface of the taken sample chip with the second focused energy beam thereby to etch the SPM-observed surface; and
a step of repeating said fourth and fifth steps only a required number of times again.

14. The method of preparing a sample chip and observing its wall surface of claim 13, wherein said first focused energy beam is a focused ion beam, and
said second focused energy beam is an argon ion beam.

15. The method of preparing a sample chip and observing its wall surface of claim 14, wherein said first step includes processing the sample chip so that a stepped portion according to difference in material is formed in a observed surface to be observed with the scanning probe microscope.

16. The method of preparing a sample chip and observing its wall surface of claim 1, wherein the sample chip to be cut off is shaped into an asymmetric form thereby to allow the observed surface of the sample chip for observation with the scanning probe microscope to be identified.

17. A system for preparing a sample chip and observing a wall surface of the sample chip, comprising:
a focused ion beam apparatus for cutting off the sample chip from a sample by etching;
a pick-up apparatus for taking up the sample chip cut away from the sample;
a sample chip holder for securing the sample chip taken up by said pick-up apparatus with an SPM-observed surface upward; and
a scanning probe microscope for observing the observed surface of the sample chip secured to said sample chip holder, and
said sample chip holder mountable in a focused ion beam irradiated position of said focused ion beam apparatus.

18. The system for preparing a sample chip and observing a wall surface of the sample chip of claim 17, wherein said scanning probe microscope includes:
a sample stage at least movable in a three-dimensional space at least for setting thereon said sample chip holder for securing the sample chip;
an argon ion beam irradiating apparatus for irradiating a surface of the sample chip with an argon ion beam substantially from a tangent direction of the sample chip surface to etch the surface in a condition where said sample stage has been moved away from said scanning probe microscope unit;
said scanning probe microscope for observing the surface of the sample chip;
a vacuum chamber for maintaining said sample stage, argon ion beam irradiating apparatus and scanning probe microscope under vacuum; and
a vacuum pump system for evacuating said vacuum chamber.

19. The system for preparing a sample chip and observing a wall surface of the sample chip of claim 17, wherein said scanning probe microscope is capable of measuring properties of the sample chip by detecting various physical quantities involved in interactions caused between a probe of said scanning probe microscope and the sample chip.

20. The system for preparing a sample chip and observing a wall surface of the sample chip of claim 19, wherein said physical quantities are physical quantities in connection with electrical properties of the sample including sample's electrical conductivity, dopant concentration, dielectric constant, electric potential, leaking magnetic field, and spin interaction.

21. The system for preparing a sample chip and observing a wall surface of the sample chip of claim 19, wherein said physical quantities are physical quantities in connection with mechanical properties of the sample including sample's hardness, friction, and elasticoviscosity.

22. The system for preparing a sample chip and observing a wall surface of the sample chip of claim 17, further comprising a cutting unit for cutting a sample surface with a diamond needle for a purpose of additionally processing the sample chip.

23. The system for preparing a sample chip and observing a wall surface of the sample chip of claim 17, wherein a voltage is applied to the sample chip to perform anodization thereby to form an insulating layer on a surface of the sample chip for a purpose of additionally processing the sample chip.

24. A system for preparing a sample chip and observing a wall surface of the sample chip, comprising:
a focused ion beam apparatus for cutting off the sample chip from a sample by etching;
a pick-up apparatus for taking up the sample chip cut away from the sample;
a sample chip holder for securing the sample chip taken up by said pick-up apparatus with an SPM-observed surface upward;
an argon ion beam irradiating apparatus for irradiating a observed surface of the sample chip with an argon ion beam substantially from a tangent direction of the observed surface of the sample chip secured to said sample chip holder; and
a scanning probe microscope for observing the observed surface of the sample chip secured to said sample chip holder, and
said sample chip holder mountable in a focused ion beam irradiated position of said focused ion beam apparatus.

25. The system for preparing a sample chip and observing a wall surface of the sample chip of claim. 17,
wherein said sample chip holder has a space for securing the sample chip located in its end face, and
said space for securing the sample chip has a shape and a size, both discernible for an operator with the eye.

26. The system for preparing a sample chip and observing a wall surface of the sample chip of claim 17,
wherein said sample chip holder has a surface coated with a conducting metal and has capabilities of causing a current to flow through the sample chip and grounding the sample chip.

27. The system for preparing a sample chip and observing a wall surface of the sample chip of claim 17,
wherein said sample chip holder has a low-melting-point metal, such as indium, on a surface thereof, and has a mechanism such that said sample chip holder and the sample chip are heated to melt the low-melting-point metal thereby to secure the sample chip and establish good conductivity between the sample chip and said sample chip holder.

28. The system for preparing a sample chip and observing a wall surface of the sample chip of claim. 17,
wherein said sample chip holder has a low-melting-point polymer on a surface thereof and has a mechanism such that said sample chip holder and the sample chip is heated to melt the low-melting-point polymer thereby to secure the sample chip and isolate the sample chip from said sample chip holder.

29. The system for preparing a sample chip and observing a wall surface of the sample chip of claim 17,
wherein said sample chip holder has a flat insulator substrate, such as Macor(R), with a plurality of electrodes thereon, and
said sample chip holder permits wiring between the electrodes thereof and electrodes of the sample chip by wire bonding, etc.

30. A pick-up apparatus comprising:
a sample stage movable at least in a three-dimensional space, on which a sample can be put;
tweezers for pinching and picking up a sample chip put on said sample stage by remote control operation;
a manipulator capable of controlling a position of said tweezers in three dimensions; and
a microscope which enables observation of positions of said tweezers and the sample chip.

31. The pick-up apparatus of claim 30, wherein said manipulator includes: a first actuating shaft for shifting a position of said tweezers in a horizontal direction; a second actuating shaft for shifting the position in a vertical direction; and a third actuating shaft for shifting the position in a normal line direction of a plane formed by said first and second actuating shafts; and fourth actuating shaft for rotating the position around said third actuating shaft.

32. The pick-up apparatus of claim 30, wherein said microscope is an optical microscope.

33. The pick-up apparatus of claim 30, wherein said microscope is a scanning electron microscope, and
the apparatus further comprises a vacuum chamber for maintaining said constituent elements in vacuum.

34. The pick-up apparatus of claim 30, wherein said microscope is a scanning ion microscope, and
the apparatus further comprises a vacuum chamber for maintaining said constituent elements in vacuum.

35. A scanning probe microscope, comprising:
a sample stage at least movable in a three-dimensional space for setting thereon a sample chip holder for securing a sample chip;
an argon ion beam irradiating apparatus for irradiating a surface of the sample chip with an argon ion beam substantially from a tangent direction of the sample chip surface to etch the surface in a condition where said sample stage has been moved away from a scanning probe microscope unit;
said scanning probe microscope unit for observing the surface of the sample chip;
a vacuum chamber for maintaining said sample stage, argon ion beam irradiating apparatus and scanning probe microscope under vacuum; and
a vacuum pump system for evacuating said vacuum chamber.
